(19) United States
(12) Patent Application Publication
(10) Pub. No.: US 2025/0264520 A1
(43) Pub. Date: Aug. 21, 2025

(54) Process Corner Simulation System Capable of Processing a Duty Cycle and Speed-based Process Corner Simulations

(71) Applicant: Realtek Semiconductor Corp., HsinChu (TW)

(72) Inventor: Chih-Chiang Chang, HsinChu (TW)

(73) Assignee: Realtek Semiconductor Corp., HsinChu (TW)

(21) Appl. No.: 18/955,993

(22) Filed: Nov. 22, 2024

(30) Foreign Application Priority Data
Feb. 19, 2024 (TW) 113105750

(51) Int. Cl. G01R 31/28; G01R 31/317

(52) U.S. Cl. CPC G01R 31/2803; G01R 31/31713; G01R 31/31727

(57) ABSTRACT

A process corner simulation system includes a frequency generator, a transistor sensitive circuit, and a process corner simulator. The frequency generator is used to generate a frequency signal. The transistor sensitive circuit is coupled to the frequency generator for receiving the frequency signal. The process corner simulator is coupled to the transistor sensitive circuit for receiving at least one output signal generated from the transistor sensitive circuit. The at least one output signal outputted from the transistor sensitive circuit includes speed information and duty cycle information. The process corner simulator uses a plurality of process corner models for generating a plurality of simulation results corresponding to different process corners according to the at least one output signal.

### BACKGROUND OF THE INVENTION

### 1. Field of the Invention

The present invention illustrates a process corner simulation system, and more particularly, a process corner simulation system capable of performing five-process corners simulations of an integrated circuit according to duty cycle information and speed information.

### 2. Description of the Prior Art

Before integrated circuit products can proceed to a mass production stage, they need to undergo a series of fine-tuning processes in fabrication (Fab) plants to ensure that the transistor components are prepared to meet special requirements during mass production. When the Fab plant performs process adjustments (say, skew wafer), it uses the direct current (DC) parameters of transistors, such as P-type/N-type transistors, tested on wafers during a wafer acceptance test (WAT) stage. These parameters serve as a benchmark to determine if the adjustments are within the customer's specified range. However, the testing data obtained from the transistors during the WAT stage is often inadequate. For example, WAT DC parameters (i.e., Idsat/Vth . . . ) do not directly correspond to the chip speed (frequency) specifications. While a ring oscillator can directly monitor the chip speed, the ring oscillator only reveals changes when the process for P-type/N-type transistors is adjusted in the same direction. This means changes are only observable when moving from a typical-typical (TT) condition to a slow-slow (SS) condition, or from the typical-typical (TT) condition to a fast-fast (FF) condition of process corners. Consequently, it cannot monitor changes when adjustments are made in different directions. Additionally, the WAT stage typically has fewer than 9 detection points distributed across an entire wafer. Given the limited testing data, it is a challenge to ascertain whether the process adjustments align with the expected target range or deviate from it. As a result, current technologies cannot mitigate local variation effects in advanced processes.

Therefore, developing a process corner simulation system for generating characteristics of the transistors under different process corners to fine-tune the manufacturing process is an important issue.

### SUMMARY OF THE INVENTION

In an embodiment of the present invention, a process corner simulation system is disclosed. The process corner simulation system comprises a frequency generator, a transistor sensitive circuit, and a process corner simulator. The frequency generator is configured to generate a frequency signal. The transistor sensitive circuit is coupled to the frequency generator and configured to receive the frequency signal. The process corner simulator is coupled to the transistor sensitive circuit and configured to receive at least one output signal generated from the transistor sensitive circuit. The at least one output signal outputted from the transistor sensitive circuit comprises speed information and duty cycle information. The process corner simulator uses a plurality of process corner models for generating a plurality of simulation results corresponding to different process corners according to the at least one output signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a process corner simulation system according to an embodiment of the present invention.

FIG. 2 is a circuit structure of a frequency generator of the process corner simulation system in FIG. 1.

FIG. 3 is a circuit structure of a transistor sensitive circuit of the process corner simulation system in FIG. 1.

FIG. 4 is a circuit structure of a first buffer chain of the process corner simulation system in FIG. 1.

FIG. 5 is a circuit structure of a second buffer chain of the process corner simulation system in FIG. 1.

FIG. 6 is a circuit structure of a third buffer chain of the process corner simulation system in FIG. 1.

FIG. 7 is an illustration of a simulation result of metal oxide semiconductor field effect transistors of the process corner simulation system in FIG. 1 under different process corners.

FIG. 8 is an illustration of a simulation result of Fin field-effect transistors of the process corner simulation system in FIG. 1 under different process corners.

### DETAILED DESCRIPTION

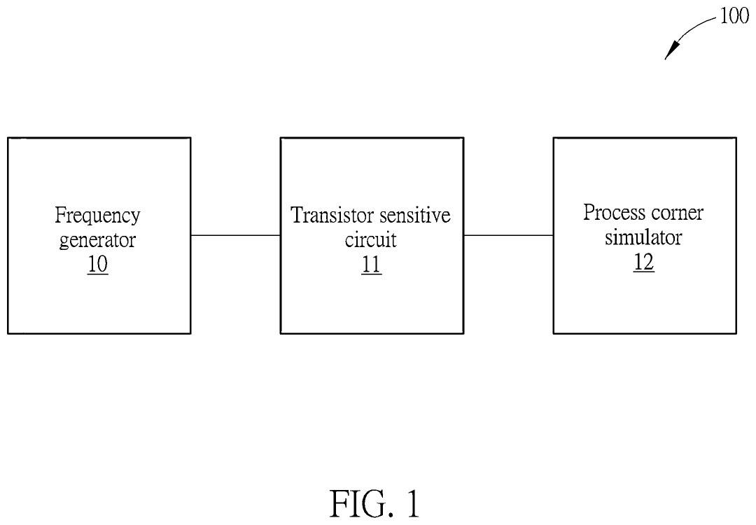

FIG. 1 is a block diagram of a process corner simulation system 100 according to an embodiment of the present invention. The process corner simulation system 100 includes a frequency generator 10, a transistor sensitive circuit 11, and a process corner simulator 12. The frequency generator 10 is used for generating a frequency signal. The transistor sensitive circuit 11 is coupled to the frequency generator 10 for receiving the frequency signal. The process corner simulator 12 is coupled to the transistor sensitive circuit 11 for receiving at least one output signal generated by the transistor sensitive circuit 11. The at least one output signal outputted from the transistor sensitive circuit 11 includes speed information and duty cycle information. Therefore, the at least one output signal can be used to conduct two-dimensional simulations of process corners. In this context, the speed information can include a response speed of the transistor after the transistor receives the output frequency signal (i.e., can be called as a “clock signal” hereafter). The response speed can be expressed in terms of frequency (Hertz). The duty cycle information may include the ratio of the time taken by the pulse (i.e., positive pulse width) to the total time (i.e., pulse period) after the transistor receives the clock signals. The process corner simulator 12 has the capability to employ a plurality of process corner models for generating a plurality of simulation results corresponding to different process corners according to the at least one output signal. Details of the process corner simulation system 100 are illustrated subsequently.

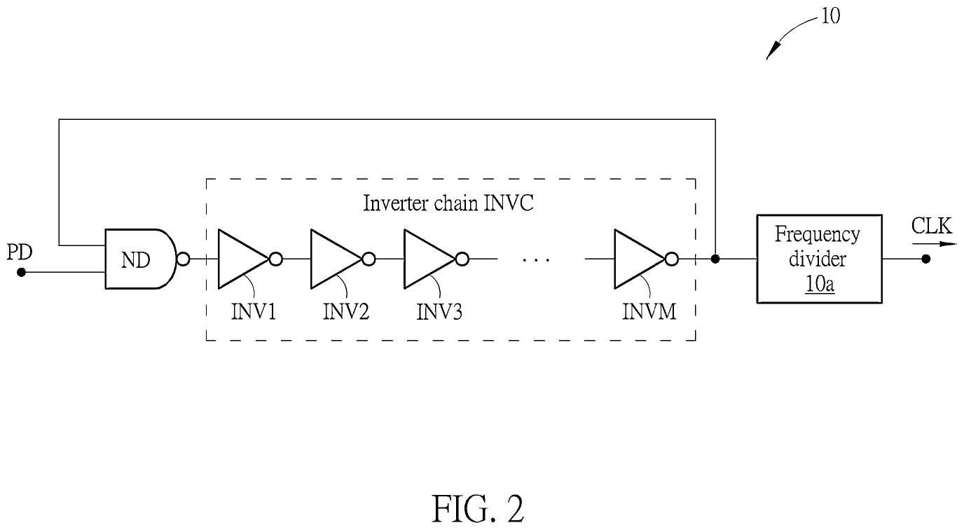

FIG. 2 is a circuit structure of the frequency generator 10 of the process corner simulation system 100. The frequency generator 10 of the process corner simulation system 100 may be a ring oscillator. The frequency generator 10 may include an inverter chain INVC, a NAND gate ND, and a frequency divider 10a. The inverter chain INVC includes an input terminal, M inverters INV1 to INVM coupled in series, and an output terminal. The NAND gate ND includes a first input terminal, a second input terminal, and an output terminal. The first input terminal is coupled to the output terminal of the inverter chain INVC. The second input terminal is used for receiving a switch signal PD. The output terminal is coupled to the input terminal of the inverter chain INVC. The frequency divider 10a is coupled to the first input terminal of the NAND gate ND for outputting the frequency signal CLK. Here, in the frequency generator 10, M is a positive even number. M can be scaled within a range of 30˜50. Moreover, the frequency divider 10a can limit a frequency range within a measurement range. For example, the frequency divider 10a can limit an upper bound of the frequency range less than 100 MHz for facilitating various measurement processes performed by test equipment or oscilloscope instruments within the frequency range. In an embodiment, the frequency signal CLK outputted by the frequency divider 10a can be measured by a testing circuit or a motherboard (system board). Further, the switch signal PD can be used for turning on or turning off the frequency generator 10. For example, when the switch signal PD is at a high voltage level, the frequency generator 10 can be turned on. When the switching signal PD is at a low voltage level, the frequency generator 10 can be turned off.

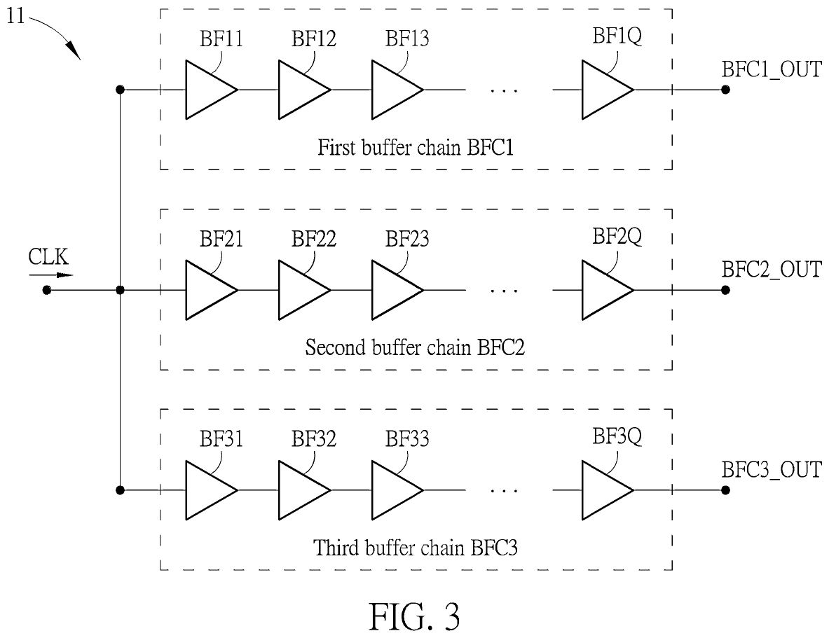

FIG. 3 is a circuit structure of the transistor sensitive circuit 11 of the process corner simulation system 100. The transistor sensitive circuit 11 may include a first buffer chain BFC1, a second buffer chain BFC2, and a third buffer chain BFC3. The first buffer chain BFC1 is coupled to the frequency generator 10 for receiving the frequency signal CLK and generating a first buffer chain output signal BFC1_OUT according to the frequency signal CLK. The first buffer chain BFC1 may include Q first buffers BF11 to BF1Q coupled in series. The second buffer chain BFC2 is coupled to the frequency generator 10 for receiving the frequency signal CLK and generating a second buffer chain output signal BFC2_OUT according to the frequency signal CLK. The second buffer chain BFC2 may include Q second buffers BF21 to BF2Q coupled in series. The third buffer chain BFC3 is coupled to the frequency generator 10 for receiving the frequency signal CLK and generating a third buffer chain output signal BFC3_OUT according to the frequency signal CLK. The third buffer chain BFC3 may include Q third buffers BF31 to BF3Q coupled in series. Q is a positive integer. Q can be scaled within a range of 300˜400. In the process corner simulation system 100, the three buffer chains BFC1 to BFC3 of the transistor sensitive circuit 11 can be different types of buffer chains. For example, in the first buffer chain BFC1, P-type metal oxide semiconductor field effect transistors and N-type metal oxide semiconductor field effect transistors align with a normal condition stipulated by a standard specification. In the second buffer chain BFC2, P-channel effects of P-type metal oxide semiconductor field effect transistors are less pronounced than what is typically observed under a normal condition stipulated by the standard specification. In the third buffer chain BFC3, N-channel effects of N-type metal oxide semiconductor field effect transistors are less pronounced than what is typically observed under a normal condition stipulated by the standard specification. Since the transistor sensitive circuit 11 can generate buffer outputs under different conditions, the process corner simulator 12 can generate process corner simulation results under different conditions. Detail configurations of the transistor sensitive circuit 11 are described below.

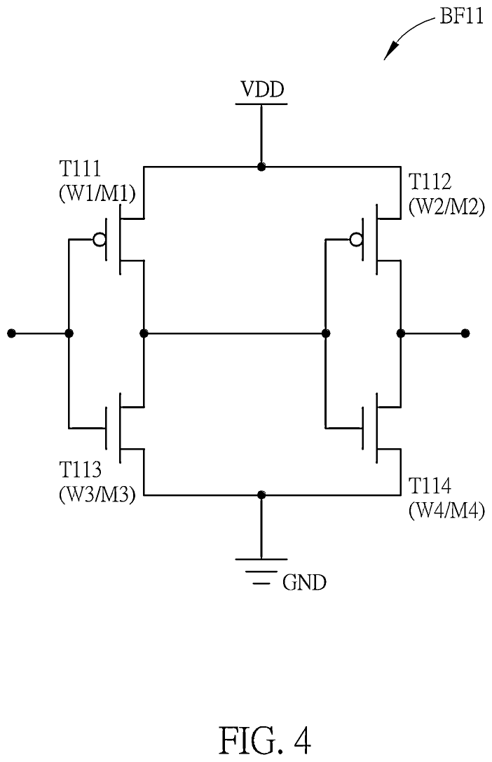

FIG. 4 is a circuit structure of the first buffer chain BFC1 of the process corner simulation system 100. As mentioned previously, the first buffer chain BFC1 may include Q first buffers BF11 to BF1Q coupled in series. Structures of the Q first buffers BF11 to BF1Q are similar. For simplicity, the first buffer BF11 is illustrated here. The first buffer BF11 includes a first transistor T111, a second transistor T112, a third transistor T113, and a fourth transistor T114. The first transistor T111 includes a first terminal, a second terminal, and a control terminal. The first terminal is used for receiving a working voltage VDD. The second transistor T112 includes a first terminal, a second terminal, and a control terminal. The first terminal is coupled to the first terminal of the first transistor T111. The control terminal is coupled to the second terminal of the first transistor T111. The third transistor T113 includes a first terminal, a second terminal, and a control terminal. The first terminal is coupled to the second terminal of the first transistor T111. The second terminal is coupled to a ground terminal GND. The control terminal is coupled to the control terminal of the first transistor T111. The fourth transistor T114 includes a first terminal, a second terminal, and a control terminal. The first terminal is coupled to the second terminal of the second transistor T112. The second terminal is coupled to the second terminal of the third transistor T113. The control terminal is coupled to the control terminal of the second transistor T112. In the first buffer chain BFC1, the first transistor T111 and the second transistor T112 are P-type metal oxide semiconductor field effect transistors. The third transistor T113 and the fourth transistor T114 are N-type metal oxide semiconductor field effect transistors. Further, channel effects of the first transistor T111, the second transistor T112, the third transistor T113, and the fourth transistor T114 align with a normal condition stipulated by a standard specification. For example, a gate width W1 of the first transistor T111 may be 225 nanometers (nm). The number of parallel connections of the first transistors T111 may be 2, such as M1=2. A gate width W2 of the second transistor T112 may be 225 nm. The number of parallel connections of the second transistors T112 may be 4, such as M2=4. A gate width W3 of the third transistor T113 may be 195 nm. The number of parallel connections of the third transistors T113 may be 2, such as M3=2. A gate width W4 of the fourth transistor T114 may be 195 nm. The number of parallel connections of the fourth transistors T114 may be 4, such as M4=4.

Further, the first transistor T111, the second transistor T112, the third transistor T113, and the fourth transistor T114 can be fin field-effect transistors. For example, the first transistor T111 and the second transistor T112 are P-channel fin field-effect transistors. The third transistor T113 and the fourth transistor T114 are N-channel fin field-effect transistors. The numbers of fins of the first transistor T111, the second transistor T112, the third transistor T113, and the fourth transistor T114 align with a normal condition stipulated by a standard specification. In the embodiment, the number of fins of the first transistor T111 can be 3. The number of parallel connections of the first transistors T111 may be 1, such as M1=1. The number of fins of the second transistor T112 can be 3.

The number of parallel connections of the second transistors T112 may be 4, such as M2=4. The number of fins of the third transistor T113 can be 3. The number of parallel connections of the third transistors T113 may be 1, such as M3=1. The number of fins of the fourth transistor T114 can be 3. The number of parallel connections of the fourth transistors T114 may be 4, such as M4=4.

The first buffer chain BFC1 can output the first buffer chain output signal BFC1_OUT. The process corner simulator 12 can use the plurality of process corner models for generating the plurality of simulation results according to the first buffer chain output signal BFC1_OUT. For example, channel effects of the transistors in the first buffer chain BFC1 correspond to the normal condition stipulated by the standard specification. Under such condition, the process corner simulator 12 can generate a plurality of simulation results and process parameters under a slow-slow (SS) model, a fast-fast (FF) model, a typical-typical (TT) model, a slow-fast (SF) model, and a fast-slow (FS) model.

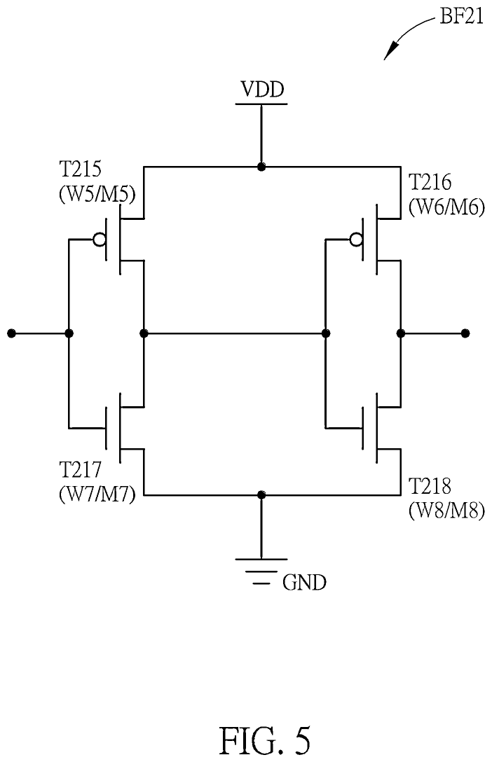

FIG. 5 is a circuit structure of the second buffer chain BFC2 of the process corner simulation system 100. As mentioned previously, the second buffer chain BFC2 may include Q second buffers BF21 to BF2Q coupled in series. Structures of the Q second buffers BF21 to BF2Q are similar. For simplicity, the second buffer BF21 is illustrated here. The second buffer BF21 includes a fifth transistor T215, a sixth transistor T216, a seventh transistor T217, and an eighth transistor T218. The fifth transistor T215 includes a first terminal, a second terminal, and a control terminal. The first terminal is used for receiving the working voltage VDD. The sixth transistor T216 includes a first terminal, a second terminal, and a control terminal. The first terminal is coupled to the first terminal of the fifth transistor T215. The control terminal is coupled to the second terminal of the fifth transistor T215. The seventh transistor T217 includes a first terminal, a second terminal, and a control terminal. The first terminal is coupled to the second terminal of the fifth transistor T215. The second terminal is coupled to the ground terminal GND. The control terminal is coupled to the control terminal of the fifth transistor T215. The eighth transistor T218 includes a first terminal, a second terminal, and a control terminal. The first terminal is coupled to the second terminal of the sixth transistor T216. The second terminal is coupled to the second terminal of the seventh transistor T217. The control terminal is coupled to the control terminal of the sixth transistor T216. In the second buffer chain BFC2, the fifth transistor T215 and the sixth transistor T216 are P-type metal oxide semiconductor field effect transistors. The seventh transistor T217 and the eighth transistor T218 are N-type metal oxide semiconductor field effect transistors. Further, P-channel effects of the fifth transistor T215 and the sixth transistor T216 are less pronounced than what is typically observed under a normal condition stipulated by the standard specification. The fifth transistor T215 and the sixth transistor T216 are called as “weak” P-type metal oxide semiconductor field effect transistors hereafter. For example, a gate width W5 of the fifth transistor T215 may be 120 nm. The number of parallel connections of the fifth transistors T215 may be 2, such as M5=2. A gate width W6 of the sixth transistor T216 may be 120 nm. The number of parallel connections of the sixth transistors T216 may be 4, such as M6=4. A gate width W7 of the seventh transistor T217 may be 195 nm. The number of parallel connections of the seventh transistors T217 may be 2, such as M7=2. A gate width W8 of the eighth transistor T218 may be 195 nm. The number of parallel connections of the eighth transistors T218 may be 4, such as M8=4.

Further, the fifth transistor T215, the sixth transistor T216, the seventh transistor T217, and the eighth transistor T218 can be fin field-effect transistors. For example, the fifth transistor T215 and the sixth transistor T216 are P-channel fin field-effect transistors. The seventh transistor T217 and the eighth transistor T218 are N-channel fin field-effect transistors. The numbers of fins of the fifth transistor T215 and the sixth transistor T216 align with a minimum condition stipulated by a standard specification. In the embodiment, the number of fins of the fifth transistor T215 can be 2. The number of parallel connections of the fifth transistors T215 may be 1, such as M5=1. The number of fins of the sixth transistor T216 can be 2. The number of parallel connections of the sixth transistors T216 may be 4, such as M6=4. The number of fins of the seventh transistor T217 can be 3. The number of parallel connections of the seventh transistors T217 may be 1, such as M7=1. The number of fins of the eighth transistor T218 can be 3. The number of parallel connections of the eighth transistors T218 may be 4, such as M8=4.

The second buffer chain BFC2 can output the second buffer chain output signal BFC2_OUT. The process corner simulator 12 can use the plurality of process corner models for generating the plurality of simulation results according to the second buffer chain output signal BFC2_OUT. For example, the P-channel effects of the second buffer chain BFC2 are less pronounced than what is typically observed under the normal condition stipulated by the standard specification. Under such condition, the process corner simulator 12 can generate a plurality of weak P-channel based simulation results and process parameters under the SS model, the FF model, the TT model, the SF model, and the FS model.

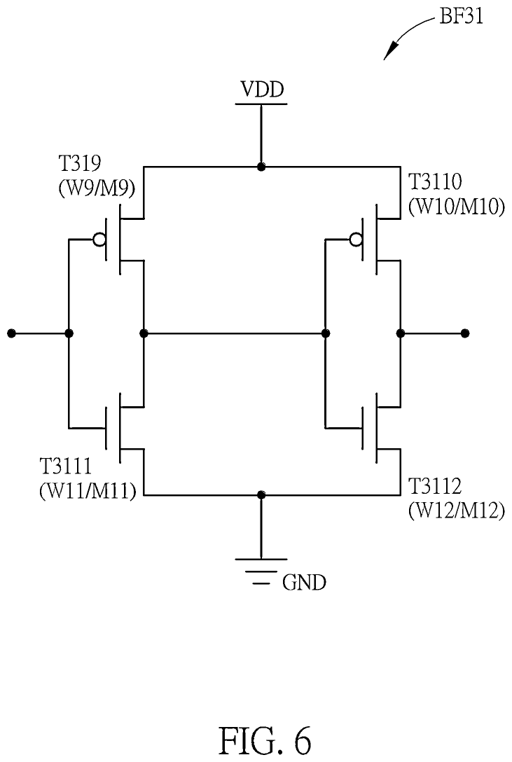

FIG. 6 is a circuit structure of the third buffer chain BFC3 of the process corner simulation system 100. As mentioned previously, the third buffer chain BFC3 may include Q third buffers BF31 to BF3Q coupled in series. Structures of the Q third buffers BF31 to BF3Q are similar. For simplicity, the third buffer BF31 is illustrated here. The third buffer BF31 includes a ninth transistor T319, a tenth transistor T3110, an eleventh transistor T3111, and a twelfth transistor T3112. The ninth transistor T319 includes a first terminal, a second terminal, and a control terminal. The first terminal is used for receiving the working voltage VDD. The tenth transistor T3110 includes a first terminal, a second terminal, and a control terminal. The first terminal is coupled to the first terminal of the ninth transistor T319. The control terminal is coupled to the second terminal of the ninth transistor T319. The eleventh transistor T3111 includes a first terminal, a second terminal, and a control terminal. The first terminal is coupled to the second terminal of the ninth transistor T319. The second terminal is coupled to the ground terminal GND. The control terminal is coupled to the control terminal of the ninth transistor T319. The twelfth transistor T3112 includes a first terminal, a second terminal, and a control terminal. The first terminal is coupled to the second terminal of the tenth transistor T3110. The second terminal is coupled to the second terminal of the eleventh transistor T3111. The control terminal is coupled to the control terminal of the tenth transistor T3110. In the third buffer chain BFC3, the ninth transistor T319 and the tenth transistor T3110 are P-type metal oxide semiconductor field effect transistors. The eleventh transistor T3111 and the twelfth transistor T3112 are N-type metal oxide semiconductor field effect transistors. Further, N-channel effects of the eleventh transistor T3111 and the twelfth transistor T3112 are less pronounced than what is typically observed under a normal condition stipulated by the standard specification. The eleventh transistor T3111 and the twelfth transistor T3112 are called as “weak” N-type metal oxide semiconductor field effect transistors hereafter. For example, a gate width W9 of the ninth transistor T319 may be 225 nm. The number of parallel connections of the ninth transistors T319 may be 2, such as M9=2. A gate width W10 of the tenth transistor T3110 may be 225 nm. The number of parallel connections of the tenth transistors T3110 may be 4, such as M10=4. A gate width W1l of the eleventh transistor T3111 may be 120 nm. The number of parallel connections of the eleventh transistors T3111 may be 2, such as M11=2. A gate width W12 of the twelfth transistor T3112 may be 120 nm. The number of parallel connections of the twelfth transistors T3112 may be 4, such as M12=4.

Further, the ninth transistor T319, the tenth transistor T3110, the eleventh transistor T3111, and the twelfth transistor T3112 can be fin field-effect transistors. For example, the ninth transistor T319 and the tenth transistor T3110 are P-channel fin field-effect transistors. The eleventh transistor T3111 and the twelfth transistor T3112 are N-channel fin field-effect transistors. The numbers of fins of the eleventh transistor T3111 and the twelfth transistor T3112 align with a minimum condition stipulated by a standard specification. In the embodiment, the number of fins of the ninth transistor T319 can be 3. The number of parallel connections of the ninth transistors T319 may be 1, such as M9=1. The number of fins of the tenth transistor T3110 can be 3. The number of parallel connections of the tenth transistors T3110 may be 4, such as M10=4. The number of fins of the eleventh transistor T3111 can be 2. The number of parallel connections of the eleventh transistors T3111 may be 1, such as M11=1. The number of fins of the twelfth transistor T3112 can be 2. The number of parallel connections of the twelfth transistors T3112 may be 4, such as M12=4.

The third buffer chain BFC3 can output the third buffer chain output signal BFC3_OUT. The process corner simulator 12 can use the plurality of process corner models for generating the plurality of simulation results according to the third buffer chain output signal BFC3_OUT. For example, the N-channel effects of the third buffer chain BFC3 are less pronounced than what is typically observed under the normal condition stipulated by the standard specification. Under such condition, the process corner simulator 12 can generate a plurality of weak N-channel based simulation results and process parameters under the SS model, the FF model, the TT model, the SF model, and the FS model.

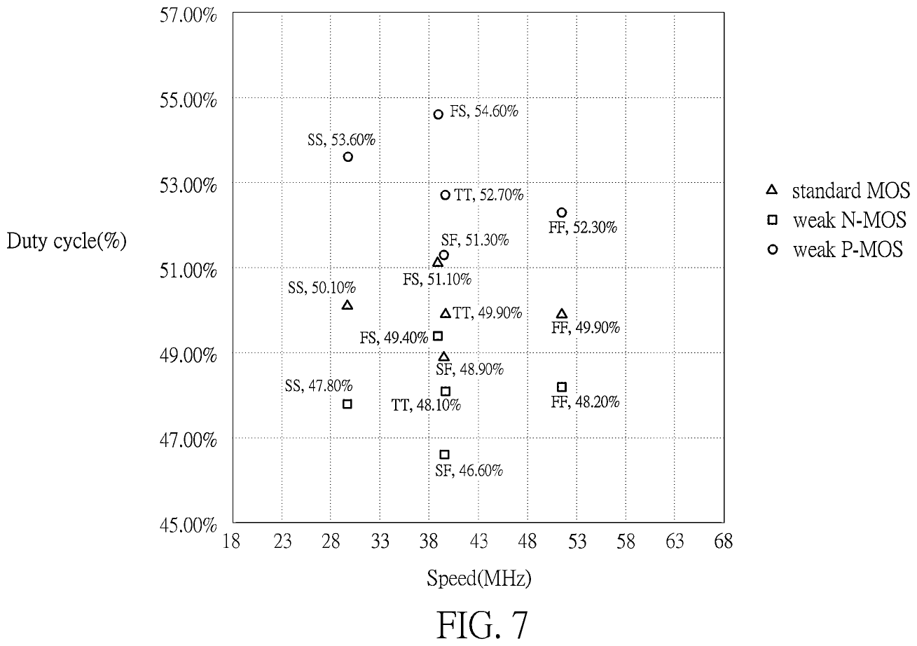

FIG. 7 is an illustration of a simulation result of metal oxide semiconductor field effect transistors of the process corner simulation system 100 under different process corners. X-axis is denoted as a speed (frequency) line. Y-axis is denoted as a duty cycle line. In FIG. 7, triangular points represent simulation results of the process corner simulator 12 under different process corner models according to the first buffer chain output signal BFC1_OUT. When all transistors align with the normal condition stipulated by the standard specification, output frequencies of the first buffer chain BFC1 generated under the TT model, the SF model, and the FS model are substantially identical. However, duty cycles of the first buffer chain BFC1 generated under the TT model, the SF model, and the FS model are different. Further, in FIG. 7, circular points represent simulation results of the process corner simulator 12 under different process corner models according to the second buffer chain output signal BFC2_OUT. Since P-channel effects of the second buffer chain BFC2 are less pronounced than what is typically observed under the normal condition stipulated by the standard specification (i.e., “weak” P-type metal oxide semiconductor field effect transistors, weak P-MOS), output frequencies of the second buffer chain BFC2 generated under the TT model, the SF model, and the FS model are substantially identical. However, duty cycles of the second buffer chain BFC2 generated under the TT model, the SF model, and the FS model are different. Further, in FIG. 7, square points represent simulation results of the process corner simulator 12 under different process corner models according to the third buffer chain output signal BFC3_OUT. Since N-channel effects of the third buffer chain BFC3 are less pronounced than what is typically observed under the normal condition stipulated by the standard specification (i.e., “weak” N-type metal oxide semiconductor field effect transistors, weak N-MOS), output frequencies of the third buffer chain BFC3 generated under the TT model, the SF model, and the FS model are substantially identical. However, duty cycles of the third buffer chain BFC3 generated under the TT model, the SF model, and the FS model are different. In FIG. 7, if the speed (frequency) line is only introduced, it is hard to distinguish the simulation results under the SF and model and the FS model. In other words, since the process corner simulation system 100 introduces a two-dimensional simulation domain (i.e., the speed axis and the duty cycle axis), skewed corner models such as the SF model and the FS model can be distinguished according to the simulation result.

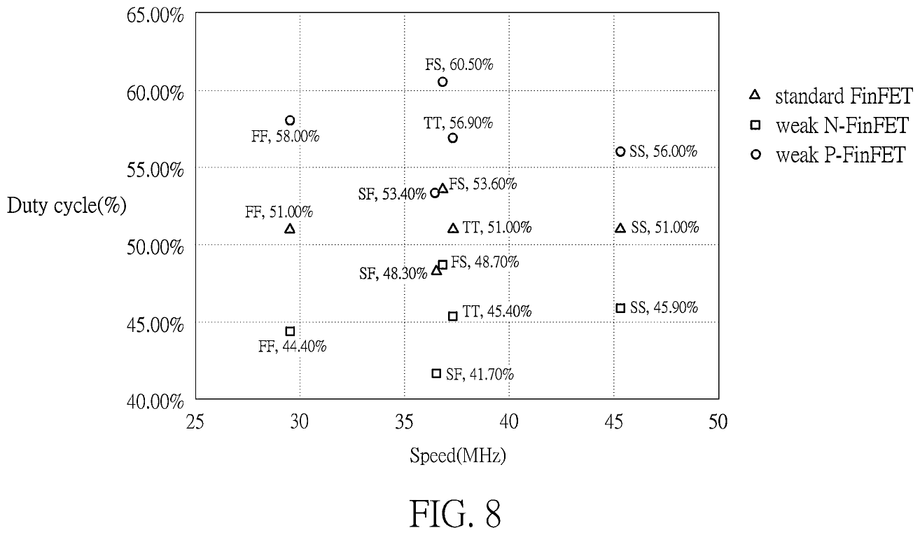

FIG. 8 is an illustration of a simulation result of fin field-effect transistors of the process corner simulation system 100 under different process corners. X-axis is denoted as a speed (frequency) line. Y-axis is denoted as a duty cycle line. All transistors in the process corner simulation system 100 are fin field-effect transistors. In FIG. 8, triangular points represent simulation results of the process corner simulator 12 under different process corner models according to the first buffer chain output signal BFC1_OUT. Circular points represent simulation results of the process corner simulator 12 under different process corner models according to the second buffer chain output signal BFC2_OUT. Square points represent simulation results of the process corner simulator 12 under different process corner models according to the third buffer chain output signal BFC3_OUT. Similarly, output frequencies of various buffer chains (BFC1, BFC2, and BFC3) generated under the TT model, the SF model, and the FS model are substantially identical. However, duty cycles of the various buffer chains (BFC1, BFC2, and BFC3) generated under the TT model, the SF model, and the FS model are different. Therefore, even if the field-effect transistors are applied to the process corner simulation system 100, since the process corner simulation system 100 introduces the two-dimensional simulation domain (i.e., the speed axis and the duty cycle axis), the skewed corner models such as the SF model and the FS model can be distinguished according to the simulation result.

Any reasonable hardware or technology modification of the process corner simulation system falls into the scope of the present invention. For example, the process corner simulation system can introduce a time-to-digital converter (TDC). The TDC can be coupled to the process corner simulator 12 for digitizing the plurality of simulation results generated by the process corner simulator 12. For example, the TDC can digitize the simulation results in FIG. 7 under various process corner models to form Table T1 to Table T3.

TABLE T1

| | Transistors under the normal condition | | |
|---|---|---|---|
| process | Speed | High power level | Low power level |
| corner | (MHz) | sampling period (Duty) | sampling period (Duty) |
| TT | 45.9 | 22 | 21 |
| SS | 53.1 | 19 | 18 |
| FF | 38.1 | 26 | 25 |
| SF | 45.4 | 21 | 22 |
| FS | 45.5 | 23 | 21 |

TABLE T2

| | Weak N-MOS | | |
|---|---|---|---|
| process | Speed | High power level | Low power level |
| corner | (MHz) | sampling period (Duty) | sampling period (Duty) |
| TT | 45.9 | 19 | 23 |
| SS | 53.1 | 17 | 20 |
| FF | 38.1 | 23 | 28 |
| SF | 45.4 | 19 | 25 |
| FS | 45.5 | 21 | 23 |

TABLE T3

| | Weak P-MOS | | |
|---|---|---|---|
| process | Speed | High power level | Low power level |
| corner | (MHz) | sampling period (Duty) | sampling period (Duty) |
| TT | 45.9 | 24 | 18 |
| SS | 53.1 | 21 | 16 |
| FF | 38.1 | 29 | 22 |
| SF | 45.4 | 24 | 20 |
| FS | 45.5 | 26 | 18 |

Here, the high power level sampling period is denoted as a time length of sampling a high power level waveform of a period of a duty cycle signal outputted by the buffer chain. The low power level sampling period is denoted as a time length of sampling a low power level waveform of the period of the duty cycle signal outputted by the buffer chain. If the process corner TT is regarded as a standard speed (100%), speed percentages of other process corners can be listed. Table T4 to Table T6 can be derived from Table T1, as illustrated below.

TABLE T4

| | |
|---|---|
| process | Transistors under the normal condition |

| corner | Speed percentage | Sample variation |
|---|---|---|
| TT | 100% | 1 |
| SS | 116% | 1 |
| FF | 84% | 1 |
| SF | 99% | −1 |
| FS | 99% | 2 |

TABLE T5

| | |
|---|---|
| process | Weak N-MOS |

| corner | Speed percentage | Sample variation |
|---|---|---|
| TT | 100% | −4 |
| SS | 116% | −3 |
| FF | 84% | −5 |
| SF | 99% | −6 |
| FS | 99% | −6 |

TABLE T6

| | |
|---|---|
| process | Weak P-MOS |

| corner | Speed percentage | Sample variation |
|---|---|---|
| TT | 100% | 6 |
| SS | 116% | 5 |
| FF | 84% | 7 |
| SF | 99% | 4 |
| FS | 99% | 8 |

In the embodiment, the process corner simulation system 100 has the capability to incorporate the TDC to form an on-chip corner detector. This integration allows the process corner simulation system 100 to offer a digital mechanism that can identify the process corner towards which a current wafer is biased.

To sum up, the present invention discloses a process corner simulation system. The process corner simulation system employs a transistor sensitive circuit under different transistor scenarios to discern differences in simulations at different process corners. These differences are based on frequency (speed) information and phase (duty cycle) information, with a particular focus on the differences in simulations of skewed corners. Thus, semiconductor manufacturers can use the simulation results from various process corners generated by the process corner simulation system to determine the position and range of process corners where the process fine-tuning results lie. As a result, by using the process corner simulation system of the present invention, the trend and extent of the process fine-tuning results can be more accurately determined.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A process corner simulation system comprising:
a frequency generator configured to generate a frequency signal;
a transistor sensitive circuit coupled to the frequency generator and configured to receive the frequency signal; and
a process corner simulator coupled to the transistor sensitive circuit and configured to receive at least one output signal generated from the transistor sensitive circuit;
wherein the at least one output signal outputted from the transistor sensitive circuit comprises speed information and duty cycle information, and the process corner simulator uses a plurality of process corner models for generating a plurality of simulation results corresponding to different process corners according to the at least one output signal.

2. The system of claim 1, wherein the frequency generator comprises:
an inverter chain comprising:
an input terminal;
M inverters coupled in series; and
an output terminal;
a NAND gate comprising:
a first input terminal coupled to the output terminal of the inverter chain;
a second input terminal configured to receive a switch signal; and
an output terminal coupled to the input terminal of the inverter chain; and
a frequency divider coupled to the first input terminal of the NAND gate and configured to output the frequency signal;
wherein M is a positive even number.

3. The system of claim 1, wherein the transistor sensitive circuit comprises:
a first buffer chain coupled to the frequency generator and configure to receive the frequency signal, and configured to generate a first buffer chain output signal according to the frequency signal;
a second buffer chain coupled to the frequency generator and configure to receive the frequency signal, and configured to generate a second buffer chain output signal according to the frequency signal; and
a third buffer chain coupled to the frequency generator and configure to receive the frequency signal, and configured to generate a third buffer chain output signal according to the frequency signal.

4. The system of claim 3, wherein the first buffer chain comprises Q first buffers coupled in series, each of the Q first buffers comprising:
a first transistor comprising:
a first terminal configured to receive a working voltage;
a second terminal; and
a control terminal;
a second transistor comprising:
a first terminal coupled to the first terminal of the first transistor;
a second terminal; and
a control terminal coupled to the second terminal of the first transistor;
a third transistor comprising:
a first terminal coupled to the second terminal of the first transistor;
a second terminal coupled to a ground terminal; and
a control terminal coupled to the control terminal of the first transistor;
a fourth transistor comprising:
a first terminal coupled to the second terminal of the second transistor;
a second terminal coupled to the second terminal of the third transistor; and
a control terminal coupled to the control terminal of the second transistor;
where Q is a positive integer.

5. The system of claim 4, wherein the first transistor and the second transistor are P-type metal oxide semiconductor field effect transistors, the third transistor and the fourth transistor are N-type metal oxide semiconductor field effect transistors, and channel effects of the first transistor, the second transistor, the third transistor, and the fourth transistor align with a normal condition stipulated by a standard specification.

6. The system of claim 4, wherein the first transistor and the second transistor are P-channel fin field-effect transistors, the third transistor and the fourth transistor are N-channel fin field-effect transistors, and fin quantities of the first transistor, the second transistor, the third transistor, and the fourth transistor align with a normal condition stipulated by a standard specification.

7. The system of claim 4, wherein the process corner simulator uses the plurality of process corner models for generating the plurality of simulation results according to the first buffer chain output signal, and the plurality of simulation results comprise simulation results generated under a slow-slow (SS) model, a fast-fast (FF) model, a typical-typical (TT) model, a slow-fast (SF) model, and a fast-slow (FS) model.

8. The system of claim 7, wherein output frequencies of the first buffer chain generated under the TT model, the SF model, and the FS model are substantially identical, and duty cycles of the first buffer chain generated under the TT model, the SF model, and the FS model are different.

9. The system of claim 3, wherein the second buffer chain comprises Q second buffers coupled in series, each of the Q second buffers comprising:
a fifth transistor comprising:
a first terminal configured to receive a working voltage;
a second terminal; and
a control terminal;
a sixth transistor comprising:
a first terminal coupled to the first terminal of the fifth transistor;
a second terminal; and
a control terminal coupled to the second terminal of the fifth transistor;
a seventh transistor comprising:
a first terminal coupled to the second terminal of the fifth transistor;
a second terminal coupled to a ground terminal; and
a control terminal coupled to the control terminal of the fifth transistor; and
an eighth transistor comprising:
a first terminal coupled to the second terminal of the sixth transistor;
a second terminal coupled to the second terminal of the seventh transistor; and
a control terminal coupled to the control terminal of the sixth transistor;
where Q is a positive integer.

10. The system of claim 9, wherein the fifth transistor and the sixth transistor are P-type metal oxide semiconductor field effect transistors, the seventh transistor and the eighth transistor are N-type metal oxide semiconductor field effect transistors, and P-channel effects of the fifth transistor and the sixth transistor are less pronounced than what is typically observed under a normal condition stipulated by a standard specification.

11. The system of claim 9, wherein the fifth transistor and the sixth transistor are P-channel fin field-effect transistors, the seventh transistor and the eighth transistor are N-channel fin field-effect transistors, and fin quantities of the fifth transistor and the sixth transistor align with a minimum condition stipulated by a standard specification.

12. The system of claim 9, wherein the process corner simulator uses the plurality of process corner models for generating the plurality of simulation results according to the second buffer chain output signal, and the plurality of simulation results comprises simulation results generated under a slow-slow (SS) model, a fast-fast (FF) model, a typical-typical (TT) model, a slow-fast (SF) model, and a fast-slow (FS) model.

13. The system of claim 12, wherein output frequencies of the second buffer chain generated under the TT model, the SF model, and the FS model are substantially identical, and duty cycles of the second buffer chain generated under the TT model, the SF model, and the FS model are different.

14. The system of claim 3, wherein the third buffer chain comprises Q third buffers coupled in series, each of the Q third buffers comprising:
a ninth transistor comprising:
a first terminal configured to receive a working voltage;
a second terminal; and
a control terminal;
a tenth transistor comprising:
a first terminal coupled to the first terminal of the ninth transistor;
a second terminal; and
a control terminal coupled to the second terminal of the ninth transistor;
an eleventh transistor comprising:
a first terminal coupled to the second terminal of the ninth transistor;
a second terminal coupled to a ground terminal; and
a control terminal coupled to the control terminal of the ninth transistor; and
a twelfth transistor comprising:
a first terminal coupled to the second terminal of the tenth transistor;
a second terminal coupled to the second terminal of the eleventh transistor; and
a control terminal coupled to the control terminal of the tenth transistor;
where Q is a positive integer.

15. The system of claim 14, wherein the ninth transistor and the tenth transistor are P-type metal oxide semiconductor field effect transistors, the eleventh transistor and the twelfth transistor are N-type metal oxide semiconductor field effect transistors, and N-channel effects of the eleventh transistor and the twelfth transistor are less pronounced than what is typically observed under a normal condition stipulated by a standard specification.

16. The system of claim 14, wherein the ninth transistor and the tenth transistor are P-channel fin field-effect transistors, the eleventh transistor and the twelfth transistor are N-channel fin field-effect transistors, and fin quantities of the eleventh transistor and the twelfth transistor align with a minimum condition stipulated by a standard specification.

17. The system of claim 14, wherein the process corner simulator uses the plurality of process corner models for generating the plurality of simulation results according to the third buffer chain output signal, and the plurality of simulation results comprises simulation results generated under a slow-slow (SS) model, a fast-fast (FF) model, a typical-typical (TT) model, a slow-fast (SF) model, and a fast-slow (FS) model.

18. The system of claim 17, wherein output frequencies of the third buffer chain generated under the TT model, the SF model, and the FS model are substantially identical, and duty cycles of the second buffer chain generated under the TT model, the SF model, and the FS model are different.

19. The system of claim 1, wherein the frequency generator is a ring oscillator.

20. The system of claim 1, further comprising:
a time-to-digital converter (TDC) coupled to the process corner simulator and configured to digitize the plurality of simulation results generated by the process corner simulator.
